(19) United States
(12) Patent Application Publication
(10) Pub. No.: US 2026/0236661 A1
(43) Pub. Date: Aug. 13, 2026

(54) HOTSPOT SEARCHING BASED ON MACHINE LEARNING

(71) Applicant: Applied Materials Israel Ltd., Rehovot (IL)

(72) Inventors: Shay ATTAL, Rehovot (IL); Aner AVAKRAT, Ohad (IL); Tung-Yuan HSIEH, Tainan City (TW)

(21) Appl. No.: 19/050,063

(22) Filed: Feb. 10, 2025

(51) Int. Cl. G06F 30/398; G06N 3/0475; G06N 3/094; G06T 7/00

(52) U.S. Cl. CPC G06F 30/398; G06N 3/0475; G06N 3/094; G06T 7/0006; G06T 2207/20081; G06T 2207/30148

(57) ABSTRACT

There is provided a system and method of hotspot searching. The method includes obtaining design data usable for manufacturing a semiconductor specimen; processing the design data using a machine learning (ML) model, to obtain a simulated image predicting appearance of an actual image of the semiconductor specimen, the ML model being previously trained for design-based image simulation to simulate one or more physical effects resulting from a manufacturing process of the specimen; extracting one or more contours from the simulated image; obtaining a metrology measurement pertaining to a metrology application based on the extracted contours; and comparing the metrology measurement with respect to a metrology rule related to the metrology application to identify one or more hotspots on the design data.

### TECHNICAL FIELD

The presently disclosed subject matter relates, in general, to the field of fabrication and examination of a semiconductor specimen, and more specifically, to machine-learning based hotspot searching.

### BACKGROUND

Current demands for high density and performance, associated with ultra large-scale integration of fabricated devices, require submicron features, increased transistor and circuit speeds, and improved reliability. As semiconductor processes progress, pattern dimensions such as line width, and other types of critical dimensions, are continuously shrunken. Such demands require formation of device features with high precision and uniformity, which, in turn, necessitates careful monitoring of the fabrication process, including automated examination of the devices while they are still in the form of semiconductor wafers.

During the semiconductor fabrication process, even minor deviations in the manufacturing steps can lead to defects that adversely affect the functionality, yield, and reliability of the resulting devices. Such variations often manifest more prominently in certain localized regions of the semiconductor design, commonly referred to as hotspots. These hotspots represent areas where the interactions between design patterns and manufacturing process conditions are most likely to produce defects, making them critical for identifying and addressing during the design and manufacturing stages.

Hotspots typically arise from intricate interactions between design patterns and process variations during the manufacturing process, such as those introduced during lithography, etching, deposition, and chemical-mechanical polishing steps. These interactions can cause issues such as critical dimension (CD) variations, overlay errors, edge roughness, or other deviations, which are particularly sensitive to process conditions. If not addressed, these localized deviations can propagate through subsequent fabrication stages, compounding their impact, and ultimately compromising the performance and reliability of the integrated circuits.

As semiconductor device geometries continue to shrink and manufacturing processes grow increasingly intricate, identifying and mitigating hotspots has become an essential challenge. Traditional methods often struggle to account for the nuanced interactions between design and process, creating a pressing need for advanced methodologies capable of detecting hotspots with higher precision and reliability, even at early stages of the design and manufacturing pipeline.

### SUMMARY

In accordance with certain aspects of the presently disclosed subject matter, there is provided a computerized system for hotspot searching, the system comprising a processing circuitry configured to obtain design data usable for manufacturing a semiconductor specimen; process the design data using a machine learning (ML) model, to obtain a simulated image predicting appearance of an actual image of the semiconductor specimen, the ML model being previously trained for design-based image simulation to simulate one or more physical effects resulting from a manufacturing process of the specimen; extract one or more contours from the simulated image; obtain a metrology measurement pertaining to a metrology application based on the extracted contours; and compare the metrology measurement with respect to a metrology rule related to the metrology application to identify one or more hotspots on the design data.

In addition to the above features, the system according to this aspect of the presently disclosed subject matter can comprise one or more of features (i) to (viii) listed below, and/or one or more of features (ix) to (xiv) listed below with respect to the methods, in any desired combination or permutation which is technically possible:
(i). The metrology application can be one of: critical dimension (CD), overlay, and roughness.
(ii). The one or more physical effects can represent a cumulative process-induced effect from a plurality of manufacturing steps including lithography, etching, deposition, polishing, and resist.
(iii). The one or more hotspots can be identified where the metrology measurement does not meet the metrology rule.
(iv). The identified hotspots are usable for correcting the design data and/or modifying the manufacturing process.
(v). The ML model has been previously trained using a training set comprising one or more image pairs, each image pair comprising an actual image acquired by an examination tool and a corresponding design image derived based on design data.
(vi). The training set can further comprise one or more augmented image pairs, each augmented image pair comprising an augmented design image generated by augmenting a design image with one or more metrology variations, and a simulated image generated by the ML model based on the augmented design image.
(vii). The ML model has been previously trained using a training set acquired over a Focus-Exposure Matrix (FEM) wafer.
(viii). The identified hotspots can be usable to provide feedback for adjusting one or more manufacturing process parameters, including focus and exposure.

In accordance with other aspects of the presently disclosed subject matter, there is provided a computerized method of training a machine learning (ML) model, the method comprising: obtaining a training set comprising one or more image pairs, each image pair comprising an actual image acquired by an examination tool and a corresponding design image derived based on design data; training the ML model using the training set, comprising, for each image pair, processing by the ML model the design image in the image pair to obtain a simulated image, and optimizing the ML model to reduce a difference between the simulated image and the actual image in the image pair; augmenting one or more design images in one or more image pairs of the training set to mimic different metrology variations expected to occur in a manufacturing process of a specimen, giving rise to one or more augmented design images; processing the one or more augmented design images by the ML model to obtain one or more simulated images, the one or more augmented design images and the one or more simulated images forming one or more new image pairs; adding the new image pairs to the training set to obtain an enriched training set; and using the enriched training set to re-train the ML model.

This aspect of the disclosed subject matter can comprise one or more of features (i) to (viii) listed above with respect to the system, mutatis mutandis, in any desired combination or permutation which is technically possible. In addition to or in lieu of the above features, this aspect can comprise one or more of features (ix) to (xiii) listed below, in any desired combination or permutation which is technically possible:
(ix). The metrology variations can be edge placement error (EPE) variations with respect to one or more design features in the one or more design images.
(x). The EPE variations can be related to a metrology application selected from CD, overlay, and roughness.
(xi). The training set can be acquired over a Focus-Exposure Matrix (FEM) wafer comprising a plurality of dies respectively printed under a plurality of process window conditions characterized by varying combinations of focus and exposure parameters, such that the ML model, upon being trained, is capable of simulating images acquired under different process window conditions.
(xii). The method can further comprise aligning the design image and the actual image in each image pair prior to processing by the ML model.
(xiii). The ML model can be a cyclic generative adversarial network (GAN).

In accordance with other aspects of the presently disclosed subject matter, there is provided a computerized method of training a machine learning (ML) model, the method comprising: obtaining a training set acquired over a Focus-Exposure Matrix (FEM) wafer, the FEM wafer comprising a plurality of dies respectively printed under a plurality of process window conditions characterized by varying combinations of focus and exposure parameters, the trainings set comprising one or more image pairs acquired for each given die corresponding to a respective process window condition, each image pair comprising an actual image acquired from the given die by an examination tool, and a corresponding design image derived based on design data of the given die; training the ML model using the training set, comprising, for each given process window condition: processing the design image in each image pair of the one or more image pairs corresponding to the given process window condition by the ML model to obtain a simulated image; and optimizing the ML model to reduce a difference between the simulated image and the actual image; wherein the ML model, upon being trained, is capable of simulating images acquired under different process window conditions.

This aspect of the disclosed subject matter can comprise one or more of features (i) to (xiii) listed above with respect to the system, mutatis mutandis, in any desired combination or permutation which is technically possible. In addition to or in lieu of the above features, this aspect can comprise the feature (xiv) listed below, in any desired combination or permutation which is technically possible:
(xiv). The training of the ML model for each given process window condition further comprises: augmenting at least one design image from the one or more image pairs corresponding to the given process window condition to mimic different metrology variations expected to occur under the given process window condition in a manufacturing process of a specimen, giving rise to at least one augmented design image; processing the at least one augmented design image by the ML model to obtain at least one simulated image, the at least one augmented design image and the at least one simulated image forming at least one new image pair; adding the at least one new image pair to the training set to obtain an enriched training set; and using the enriched training set to re-train the ML model.

In accordance with other aspects of the presently disclosed subject matter, there is provided a non-transitory computer readable medium comprising instructions that, when executed by a computer, cause the computer to perform a method of hotspot searching, the method comprising: obtaining design data usable for manufacturing a semiconductor specimen; processing the design data using a machine learning (ML) model, to obtain a simulated image predicting appearance of an actual image of the semiconductor specimen, the ML model being previously trained for design-based image simulation to simulate one or more physical effects resulting from a manufacturing process of the specimen; extracting one or more contours from the simulated image; obtaining a metrology measurement pertaining to a metrology application based on the extracted contours; and comparing the metrology measurement with respect to a metrology rule related to the metrology application to identify one or more hotspots on the design data.

This aspect of the disclosed subject matter can comprise one or more of features (i) to (xiv) listed above, mutatis mutandis, in any desired combination or permutation which is technically possible.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2 illustrates a generalized flowchart of runtime hotspot searching using a trained ML model in accordance with certain embodiments of the presently disclosed subject matter.

FIG. 3 illustrates a generalized flowchart of training the ML model usable for hotspot searching in accordance with certain embodiments of the presently disclosed subject matter.

FIG. 4 illustrates a generalized flowchart of training the ML model using a FEM wafer in accordance with certain embodiments of the presently disclosed subject matter.

FIG. 5 illustrates a generalized flowchart of applying image augmentation to enrich the training set of a FEM wafer and subsequently re-training of the ML model according to certain embodiments of the presently disclosed subject matter.

FIG. 6 shows a schematic illustration of the training process for the ML model as described above with reference to block 304 in accordance with certain embodiments of the presently disclosed subject matter.

FIG. 7 shows a schematic illustration of an FEM wafer in accordance with certain embodiments of the presently disclosed subject matter.

FIG. 8 illustrates examples of augmented design images for different metrology applications in accordance with certain embodiments of the presently disclosed subject matter.

### DETAILED DESCRIPTION OF EMBODIMENTS

The accurate identification and mitigation of hotspots, design-specific regions susceptible to manufacturing defects or process-induced variations, pose significant challenges in ensuring the reliability and performance of fabricated integrated circuits (ICs), particularly as semiconductor devices continue to scale down in size. Detecting hotspots early in the design or manufacturing process is crucial, enabling timely design corrections, process optimizations, and targeted metrology efforts to address potential failure points before they propagate into large-scale production.

Traditional methods for hotspot detection suffer from various limitations. By way of example, one widely adopted method for hotspot detection in semiconductor manufacturing is lithography simulation, also referred to as aerial imaging simulation. This technique involves simulating the optical imaging process during photolithography to predict areas in a design where patterning challenges might arise. Lithography simulation operates by modeling the optical transfer function of the lithographic scanner or stepper, including components such as the light source, projection optics, and reticle patterns. It aims to determine whether the projected pattern can be accurately printed on the wafer by applying a binary printing threshold to the simulated aerial image. The output is typically a simplified binary representation of the anticipated printed pattern.

While lithography simulation is a useful tool for early-stage design checks, it is inherently limited in scope and accuracy. Specifically, it only simulates the lithographic imaging process and the effects directly related to it. However, lithography represents just one step in the highly complex semiconductor manufacturing process. Downstream processes, such as resist application and development, etching, deposition, and chemical-mechanical polishing (CMP), introduce additional physical effects that significantly impact the final pattern on the wafer. For example, resist behavior during exposure and development can introduce non-linear effects, such as line edge roughness, while etching can lead to critical dimension (CD) loss or profile distortion. These effects are entirely outside the scope of traditional lithography simulations, which consequently fail to provide a holistic representation of the final wafer.

Therefore, complex process interactions, such as variations in resist chemistry, etch bias, and multi-layer deposition effects, cannot be adequately captured within the framework of lithography simulation. As a result, the predictions generated by lithography simulation frequently exhibit discrepancies when compared to the actual patterns formed on the wafer. These discrepancies often manifest as missed hotspots or false positives in the simulation output, undermining its effectiveness and accuracy in guiding design corrections and process optimizations.

Another commonly used approach is wafer image inspection, where actual images of fabricated wafers are analyzed to identify potential hotspots. Advanced inspection tools, such as Scanning Electron Microscopes (SEMs) or optical inspection tools, are used to capture high-resolution images of the wafer. However, wafer image inspection is inherently reactive, as it can only identify issues after a wafer has been processed. This post-fabrication nature makes it difficult to implement corrective measures at an early stage, and the high-resolution imaging required for detailed analysis can be time-consuming and resource-intensive.

Other conventional solutions may combine rule-based design checks and pattern-matching techniques to flag potentially problematic regions based on pre-defined heuristics and historical data. However, these methods tend to be limited in their ability to generalize to new designs and process conditions, especially as device geometries shrink and process complexities increase. The rigidity of rule-based methods often results in oversights or excessive false positives, undermining their effectiveness in addressing modern hotspot detection challenges.

Accordingly, certain embodiments of the presently disclosed subject matter propose a machine learning (ML)-based hotspot searching system, which does not have one or more of the disadvantages described above. In certain embodiments of the present disclosure, the ML-based system utilizes a trained ML model to process design data, such as CAD layouts, and generate simulated images that accurately represent the real-world physical effects observed in fabricated wafers. These simulated images surpass the capabilities of lithography simulation by accounting for complex process phenomena, such as resist behavior, etching artifacts, and other manufacturing nuances. By performing contour extraction and metrology measurements on the simulated images, the system can accurately identify potential hotspots early in the design and manufacturing process, as will be detailed below.

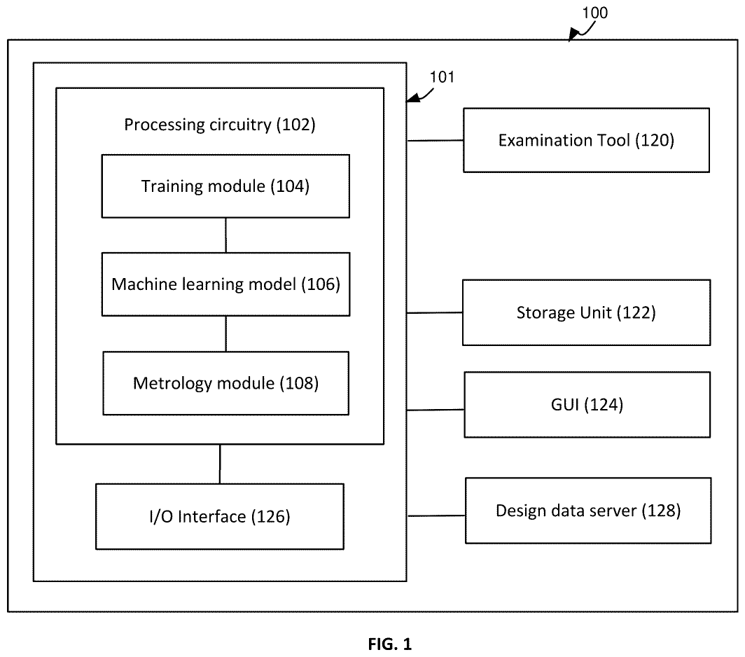

Bearing this in mind, attention is drawn to FIG. 1 illustrating a functional block diagram of an examination system in accordance with certain embodiments of the presently disclosed subject matter.

The examination system 100 illustrated in FIG. 1 can be used for examination of a semiconductor specimen as part of the specimen fabrication process. As described above, the examination referred to herein can be construed to cover any kind of operations related to defect inspection/detection, defect review, defect classification, nuisance filtration, segmentation, and/or metrology operations, etc., with respect to the specimen. System 100 comprises one or more examination tools 120 configured to scan a specimen and capture images thereof to be further processed for various examination applications.

The term “examination tool(s)” used herein should be expansively construed to cover any tools that can be used in examination-related processes, including, by way of non-limiting example, scanning (in a single or in multiple scans), imaging, sampling, reviewing, measuring, classifying, and/or other processes provided with regard to the specimen or parts thereof. Without limiting the scope of the disclosure in any way, it should also be noted that the examination tools can be implemented as inspection machines of various types, such as optical inspection machines, electron beam inspection machines (e.g., a Scanning Electron Microscope (SEM), an Atomic Force Microscopy (AFM), or a Transmission Electron Microscope (TEM), etc.), and so on.

In some embodiments of the present disclosure, at least one of the examination tools 120 has metrology capabilities and can be configured to capture images and perform metrology operations on the captured images. Such an examination tool is also referred to as a metrology tool.

One example of a metrology tool used within the examination system is a Critical Dimension Scanning Electron Microscope (CD-SEM). CD-SEM is a specialized tool designed to capture high-resolution images of semiconductor structures and perform metrology operations on those structures for different metrology applications. By way of example, the CD-SEM can be used to obtain critical dimension (CD) measurements with respect to certain structural features on the specimen to determine if they meet the design specifications. In another example, the CD-SEM's metrology capabilities can be leveraged to measure critical metrics between layers, such as overlay, to assess whether these dimensions remain within acceptable limits.

In some embodiments, optionally, in addition to or in lieu of the metrology tool, the one or more examination tools 120 can include one or more inspection tools and/or one or more review tools. In some cases, an inspection tool can be configured to scan a specimen (e.g., an entire wafer, an entire die, or portions thereof) to capture inspection images (typically, at a relatively high-speed and/or low-resolution) for detection of potential defects (i.e., defect candidates). During inspection, the wafer can move at a step size relative to the detector of the inspection tool (or the wafer and the tool can move in opposite directions relative to each other) during the exposure, and the wafer can be scanned step-by-step along swaths of the wafer by the inspection tool, where the inspection tool images a part/portion (within a swath) of the specimen at a time. By way of example, the inspection tool can be an optical inspection tool. At each step, light can be detected from a rectangular portion of the wafer, and such detected light is converted into multiple intensity values at multiple points in the portion, thereby forming an image corresponding to the part/portion of the wafer. For instance, in optical inspection, an array of parallel laser beams can scan the surface of a wafer along the swaths. The swaths are laid down in parallel rows/columns contiguous to one another, to build up, swath-at-a-time, an image of the surface of the wafer. For instance, the tool can scan a wafer along a swath from up to down, then switch to the next swath and scan it from down to up, and so on and so forth, until the entire wafer is scanned and inspection images of the wafer are collected.

In some cases, a review tool can be configured to capture review images of at least some of the defect candidates detected by inspection tools for ascertaining whether a defect candidate is indeed a defect of interest (DOI). Such a review tool is usually configured to inspect fragments of a specimen, one at a time (typically, at a relatively low-speed and/or high-resolution). By way of example, the review tool can be an electron beam tool, such as, e.g., a scanning electron microscope (SEM), etc. An SEM is a type of electron microscope that produces images of a specimen by scanning the specimen with a focused beam of electrons. The electrons interact with atoms in the specimen, producing various signals that contain information on the surface topography and/or composition of the specimen. An SEM is capable of accurately inspecting and measuring features during the manufacture of semiconductor wafers.

The various examination tools can be different tools located at the same or at different locations, or integrated as a single tool operated in different modes. In some cases, the same examination tool can provide low-resolution image data and high-resolution image data. The resulting image data (low-resolution image data and/or high-resolution image data) can be transmitted-directly or via one or more intermediate systems-to system 101. The present disclosure is not limited to any specific type of examination tools and/or the resolution of image data resulting from the examination tools.

According to certain embodiments of the presently disclosed subject matter, the examination system 100 comprises a computer-based system 101 operatively connected to the examination tool 120, and capable of ML-based hotspot searching. System 101 is also referred to as a hotspot searching system.

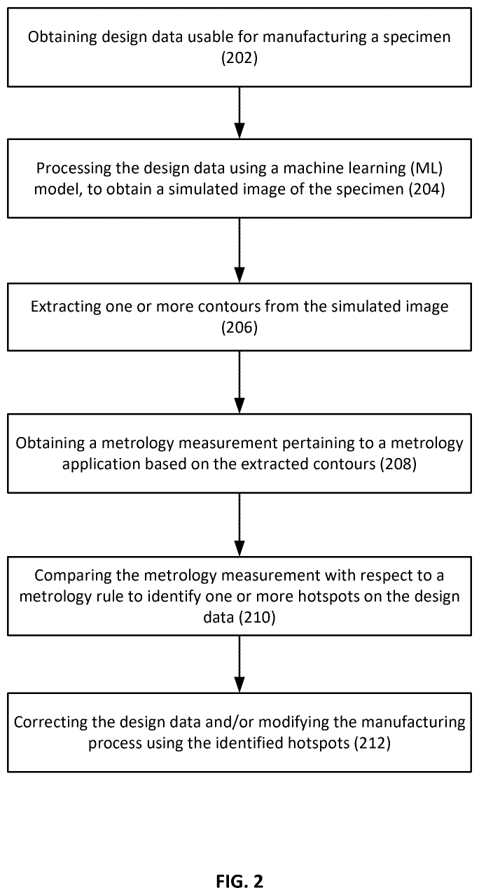

System 101 includes a processing circuitry 102 operatively connected to a hardware-based I/O interface 126 and configured to provide processing necessary for operating the system, as further detailed with reference to FIGS. 2-5. The processing circuitry 102 can comprise one or more processors (not shown separately) and one or more memories (not shown separately). The one or more processors of the processing circuitry 102 can be configured to, either separately or in any appropriate combination, execute several functional modules in accordance with computer-readable instructions implemented on a non-transitory computer-readable memory comprised in the processing circuitry. Such functional modules are referred to hereinafter as comprised in the processing circuitry.

According to certain embodiments, system 101 can be configured as a runtime hotspot searching system using a trained machine learning (ML) system. In such cases, one or more functional modules comprised in the processing circuitry 102 of system 101 can comprise a trained ML model 106 that was previously trained during a training/setup phase, and a metrology module 108 operatively connected to the ML model 106.

Specifically, the processing circuitry 102 can be configured to obtain, via an I/O interface 126, design data usable for manufacturing a semiconductor specimen. The trained ML model 106 can be used to process the design data to obtain, as output, a simulated image predicting appearance of an actual image of the semiconductor specimen. The ML model has been previously trained for design-based image simulation to simulate one or more physical effects resulting from a manufacturing process of the specimen.

The metrology module 108 can be configured to extract one or more contours from the simulated image, obtain a metrology measurement pertaining to a metrology application based on the extracted contours and compare the metrology measurement with respect to a metrology rule related to the metrology application to identify one or more hotspots on the design data.

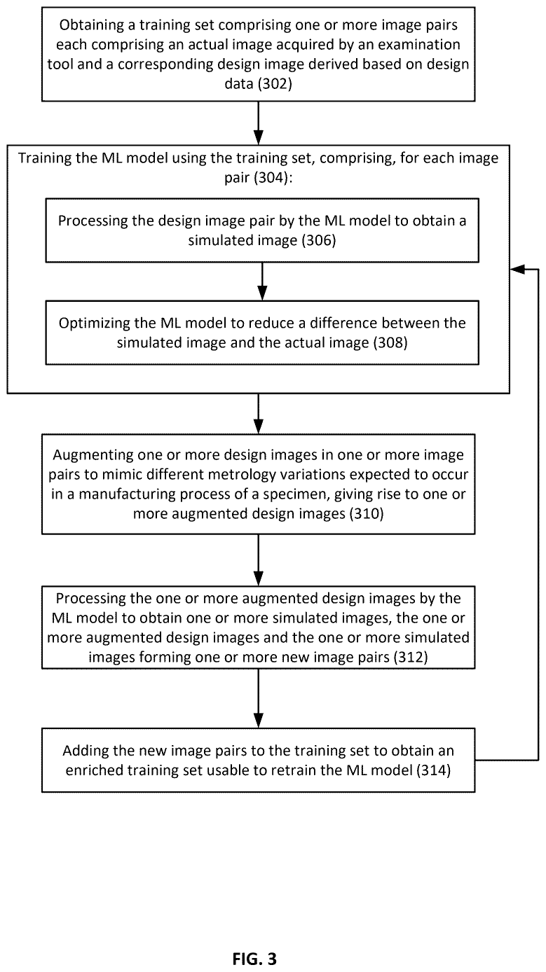

In some embodiments, system 101 can be configured as a training system capable of training the ML model 106 during a training/setup phase. In such cases, one or more functional modules comprised in the processing circuitry 102 of system 101 can include a training module 104, and an ML model 106 to be trained (i.e., the initially constructed model that is not yet trained). Specifically, the training module 104 can be configured to obtain a specific training set, and use the training set to train the ML model 106, as will be detailed below with respect to FIGS. 3-5.

According to certain embodiments, the ML model 106 can be implemented as various types of ML models, such as, e.g., decision tree, Support Vector Machine (SVM), Artificial Neural Network (ANN), regression model, transformer, Bayesian network, or ensembles/combinations thereof, etc. The learning algorithms used by the ML models can be any of the following: supervised learning, unsupervised learning, self-supervised, semi-supervised learning, or a combination thereof, etc. The presently disclosed subject matter is not limited to the specific types of the ML models or the specific types of learning algorithms used by the ML models.

By way of example, in some cases the ML model can be implemented as a deep neural network (DNN). DNN can comprise multiple layers organized in accordance with respective DNN architecture. By way of non-limiting example, the layers of DNN can be organized in accordance with architecture of a Convolutional Neural Network (CNN), Recurrent Neural Network, Recursive Neural Networks, autoencoder, Generative Adversarial Network (GAN), or otherwise. Optionally, at least some of the layers can be organized into a plurality of DNN sub-networks. Each layer of DNN can include multiple basic computational elements (CE), typically referred to in the art as dimensions, neurons, or nodes.

The weighting and/or threshold values associated with the CEs of a DNN and the connections thereof can be initially selected prior to training, and can be further iteratively adjusted or modified during training to achieve an optimal set of weighting and/or threshold values in a trained DNN. After each iteration, a difference can be determined between the actual output produced by DNN module and the target output associated with the respective training set of data. The difference can be referred to as an error value. Training can be determined to be complete when a loss/cost function indicative of the error value is less than a predetermined value, or when a limited change in performance between iterations is achieved. A set of input data used to adjust the weights/thresholds of a DNN is referred to as a training set.

It is noted that the teachings of the presently disclosed subject matter are not bound by the specific architecture of the ML model as described above.

It is to be noted that while certain embodiments of the present disclosure refer to the processing circuitry 102 being configured to perform the above-recited operations, the functionalities/operations of the aforementioned functional modules can be performed by the one or more processors in processing circuitry 102 in various ways. By way of example, the operations of each functional module can be performed by a specific processor, or by a combination of processors. The operations of the various functional modules, such as the ML model processing, the contour extraction, and the metrology operations, etc., can thus be performed by respective processors (or processor combinations) in the processing circuitry 102, while, optionally, these operations may be performed by the same processor. The present disclosure should not be limited to being construed as one single processor always performing all the operations.

In some cases, additionally to system 101, the examination system 100 can comprise one or more additional examination modules, such as, e.g., defect detection module, Automatic Defect Review (ADR) module, Automatic Defect Classification (ADC) module, additional metrology operation module, and/or other examination modules which are usable for examination of a semiconductor specimen upon fabrication. The one or more examination modules can be implemented as stand-alone computers, or their functionalities (or at least part thereof) can be integrated with the examination tools 120. In some cases, the output of system 101, e.g., the simulated image, and/or the identified hotspots, can be provided to the one or more additional examination modules for further processing.

According to certain embodiments, system 100 can comprise a storage unit 122. The storage unit 122 can be configured to store any data necessary for operating system 101, e.g., data related to input and output of system 101, as well as intermediate processing results generated by system 101. By way of example, during training, the storage unit 122 can be configured to store the training set and the enriched training set usable for training the ML model. In some cases, system 100 can also comprise a design data server 128 configured to store design data and/or derivatives thereof (such as design images derived therefrom). Accordingly, the input data as required can be retrieved from the storage unit 122 and design data server 128, and provided to the processing circuitry 102 for further processing. The output of the system 101, such as, e.g., the simulated image, and/or the identified hotspots, can be sent to storage unit 122 to be stored.

In some embodiments, system 100 can optionally comprise a computer-based Graphical User Interface (GUI) 124 which is configured to enable user-specified inputs related to system 101. For instance, the user can be presented with a visual representation of the design data of a specimen (for example, by a display forming part of GUI 124). The user may be provided, through the GUI, with options of defining certain operation parameters. The user may also view the operation results or intermediate processing results, such as, e.g., the simulated image, and/or the identified hotspots, etc., on the GUI.

In some cases, system 101 can be further configured to send, via I/O interface 126, the operation results to the examination tool 120 for further processing. In some cases, system 101 can be further configured to send the results to external systems (e.g., Yield Management System (YMS) of a fabrication plant (fab)). A yield management system (YMS) in the context of semiconductor manufacturing is a data management, analysis, and tool system that collects data from the fab, especially during manufacturing ramp-ups, and helps engineers find ways to improve yield. A YMS helps semiconductor manufacturers and fabs manage high volumes of production analysis with fewer engineers. These systems analyze the yield data and generate reports. A YMS can be used by Integrated Device Manufacturers (IMD), fabs, fabless semiconductor companies, and Outsourced Semiconductor Assembly and Test (OSAT).

Those versed in the art will readily appreciate that the teachings of the presently disclosed subject matter are not bound by the system illustrated in FIG. 1. Each system component and module in FIG. 1 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIG. 1.

Each component in FIG. 1 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

It should be noted that the examination system illustrated in FIG. 1 can be implemented in a distributed computing environment, in which one or more of the aforementioned components and functional modules shown in FIG. 1 can be distributed over several local and/or remote devices. By way of example, the examination tool 120, and the system 101 can be located at the same entity (in some cases hosted by the same device) or distributed over different entities. By way of another example, as described above, in some cases, system 101 can be configured as a training system for training the ML system, while in some other cases, system 101 can be configured as a runtime system using the trained ML system. The training system and the runtime system can be located at the same entity (in some cases hosted by the same device), or distributed over different entities, depending on specific system configurations and implementation needs.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

It should be further noted that in some embodiments at least some of the examination tool 120, storage unit 122, design data server 128 and/or GUI 124 can be external to the examination system 100 and operate in data communication with systems 100 and 101 via I/O interface 126. System 101 can be implemented as stand-alone computer(s) to be used in conjunction with the examination tools, and/or with the additional examination modules as described above. Alternatively, the respective functions of the system 101 can, at least partly, be integrated with one or more examination tools 120, thereby facilitating and enhancing the functionalities of the examination tools in examination-related processes.

While not necessarily so, the process of operations of systems 101 and 100 can correspond to some or all of the stages of the methods described with respect to FIGS. 2-5. Likewise, the methods described with respect to FIGS. 2-5 and their possible implementations can be implemented by systems 101 and 100. It is therefore noted that embodiments discussed in relation to the methods described with respect to FIGS. 2-4 can also be implemented, mutatis mutandis as various embodiments of the systems 101 and 100, and vice versa.

Referring to FIG. 2, there is illustrated a generalized flowchart of runtime hotspot searching using a trained ML model in accordance with certain embodiments of the presently disclosed subject matter.

Design data usable for manufacturing a semiconductor specimen can be obtained (202) as input (e.g., by the trained ML module 106 in the processing circuitry 102). Design data used herein should be broadly construed to refer to any digital representation of the structural layout or intent for fabricating a semiconductor device.

It is noted that references herein to design data pertain to data usable for manufacturing a semiconductor specimen through multiple processing steps. The specimen is typically composed of multiple layers, and the design data used in the present disclosure may include one or more layers of design information corresponding to the specimen. It should be understood that the present disclosure is not limited by the number of layers in the design data or in the specimen to be manufactured, nor by the number of processing steps in the manufacturing process. The disclosed concepts are applicable across various scenarios involving different specimen configurations and manufacturing complexities.

The design data can take various forms, including but not limited to, e.g., raw design intent, design images derived therefrom, or any post-Optical Proximity Correction (OPC) design data.

Raw design intent refers to the initial digital representation of the semiconductor layout, typically created by designers in the form of Computer-Aided Design (CAD) data (or other forms, depending on the tools and formats used in semiconductor design workflows). It may include information on the placement and routing of features, such as transistors, interconnects, and other circuit elements. The design intent may specify the features and patterns for multiple layers of the device, each corresponding to a distinct processing step in the manufacturing process.

In some cases, the raw design intent may be transformed into a design image that represents the layout in a manner suitable for manufacturing processes. By way of example, the relevant layer(s) or sub-region(s) of the design layout, often a vector-based or polygon-based layout, can be converted into a rasterized format, resulting in a design image that visually depicts the image pattern intended to be formed on the wafer, often without the process-related variations that might appear in the actual image.

In some cases, the design intent can be processed by Optical Proximity Correction (OPC), which is a process in semiconductor manufacturing that modifies the design data to compensate for optical distortions during lithography. In such cases, the design data may refer to the post-OPC design data including corrected features to ensure that the printed patterns on the wafer accurately reflect the intended design.

The design data can be processed (204) using a trained ML model (e.g., the ML model 106), to obtain a simulated image predicting the appearance of an actual image of the semiconductor specimen. The ML model has been specifically trained during a training phase for design-based image simulation (as will be described below in further detail with reference to FIGS. 3-5), enabling it to simulate one or more physical effects resulting from the manufacturing process of the specimen, so as to predict the final wafer appearance.

The manufacturing process of a semiconductor specimen typically comprises multiple interdependent sub-processes, such as lithography, etching, deposition, polishing, and implantation, among others. In some cases, the one or more physical effects can be regarded as representing a cumulative process-induced effect from a plurality of manufacturing steps/sub-processes as listed above.

Lithography projects the design patterns onto a photosensitive resist layer using a scanner or stepper, resulting in a patterned resist layer that serves as a mask for subsequent processes. Etching can remove material selectively from the wafer surface to form the desired patterns. Deposition, such as chemical vapor deposition (CVD) or atomic layer deposition (ALD), adds material, such as silicon dioxide, silicon nitride, metals (e.g., copper, tungsten), or dielectrics, to the wafer, creating thin films used for electrical insulation, conductivity, or structural layers. A polishing process, such as Chemical-Mechanical Polishing (CMP), can planarize the wafer surface to ensure uniformity and prepare for subsequent layers. The implantation process can introduce dopants into the silicon to modify its electrical properties.

Each of these sub-processes may introduce distinct physical effects that collectively determine the final appearance of the wafer. The simulated image predicts the final wafer appearance, representing how the design patterns will manifest after the entire sequence of manufacturing processes. While conventional approaches rely on aerial simulation to model only the lithography process, it does not account for the downstream processes and their cumulative impact on the patterns. In contrast, the ML model in the present disclosure predicts the wafer's final representation after all such processes, capturing the aggregate outcomes of the complete manufacturing workflow. In other words, the ML model does not simulate these sub-processes independently, but rather integrates their cumulative effects into a single simulation, resulting in an accurate representation of the final wafer appearance. This holistic approach addresses the limitations of solutions like aerial simulation, which only predict patterns at the lithography stage and fail to account for the downstream processes that significantly impact the final outcome.

It is to be noted that sub-processes such as etching, deposition, polishing, and implantation typically occur after lithography within a given layer of the semiconductor manufacturing process. However, depending on the specific manufacturing workflow and the layer being processed, these steps may also interleave with or precede lithography as part of the broader fabrication sequence. For purpose of illustration and exemplification, there is now provided a brief description of these sub-processes and their associated physical effects.

It is to be noted that the above-listed sub-processes represent only a subset of the broader set of interdependent steps involved in the semiconductor manufacturing process. Additional processes, such as annealing, cleaning, etc., may also be included. The present disclosure is not limited to the specific processes described herein, and may encompass all or part of such processes and their associated effects that may be relevant to the manufacturing of semiconductor specimens.

The ML model achieves this simulation capability through a specialized training process that directly correlates design data with actual wafer images. Specifically, the ML model has been previously trained using a training set comprising one or more image pairs, each image pair comprising an actual image acquired by an examination tool (such as, e.g., a Scanning Electron Microscope (SEM), which captures the physical patterns formed on the wafer during the manufacturing process) and a corresponding design image derived based on design data, representing the intended layout or structure for that portion of the specimen. This ensures the ML model learns to associate design intent with the final fabricated patterns, effectively capturing the holistic outcomes of the manufacturing process.

This training process enables the ML model to capture complex patterns and variations introduced by physical phenomena such as lithography, etching, deposition, polishing, and resist behavior. By iteratively optimizing the ML model to minimize the differences between the simulated images it generates and the actual images from the training set, the model learns to incorporate all relevant process-induced effects into its predictions. The details of the training process, including data augmentation techniques and use of focus-exposure matrix (FEM) wafers, will be further described below with reference to FIGS. 3-5.

Continuing with the process of FIG. 2, one or more contours can be extracted (206) (e.g., by the metrology module 108) from the simulated image. Contours represent the boundaries or edges of the patterns visible in the simulated image and are critical for identifying the geometric features of the design. The contour extraction can be performed using various contour extraction or image segmentation techniques. By way of example, in some cases, edge-detection algorithms (e.g., Canny, Sobel) may be employed to detect the boundaries of the features/structures within the simulated image. In some other cases, machine learning (ML)-based segmentation can be utilized, where ML models trained on annotated images (annotated with contours/segments) can be used for accurate segmentation of the contours in the image. Alternatively, in some cases, region-based segmentation (e.g., clustering methods) and/or thresholding techniques could be implemented to separate the structures, based on pixel intensity differences or texture patterns. By extracting the contours, the system can derive geometric and positional information on the simulated patterns, enabling downstream metrology measurements.

It is to be noted that the above examples are provided for exemplary purposes only, and the contour extraction used herein is not limited to any specific method, allowing it to possibly adapt, based on the specific imaging requirements and system configurations.

A metrology measurement pertaining to a metrology application can be obtained (208) (e.g., by the metrology tool 120) based on the extracted contours. The metrology application refers to a specific aspect of the pattern's geometry or quality to be assessed. Examples of metrology applications can include (but are not limited to): critical dimension (CD), overlay, and roughness, etc. CD may include measurements of feature sizes/dimensions/angles such as, e.g., line widths, spacing between lines, contact hole diameters, sidewall angle, or trench depth, etc. Overlay assesses the alignment between layers, determining the positional accuracy of features relative to underlying patterns. Roughness quantifies variations in the edges or surfaces of features, often characterized as line-edge roughness (LER) or line-width roughness (LWR).

The metrology measurement can be compared (210) (e.g., by the metrology module 108) with respect to a metrology rule or spec related to the metrology application to identify one or more hotspots on the design data. A metrology rule/spec generally defines the acceptable range or threshold for the measurement, ensuring that the feature meets design and process requirements. These rules/specifications can be typically established based on design intent, manufacturing tolerances, and device performance requirements. The metrology rule may include criteria related to various metrology applications, such as critical dimension (CD), overlay, and roughness, etc.

By way of example, a metrology rule related to CD may define acceptable minimum and maximum feature sizes, such as a gate width tolerance of 20±1 nm. Another metrology rule related to CD may define a target sidewall slope/angle, e.g., 90°±2°. By way of another example, a metrology rule related to overlay may specify the maximum allowable misalignment between layers, such as <10 nm. A metrology rule related to roughness may set limits on edge irregularities, such as an LER below 3 nm RMS. As used herein, RMS (Root Mean Square) refers to a statistical measure of the average deviation of an edge's position from its ideal shape, commonly used to quantify line edge roughness (LER).

In some embodiments, the one or more hotspots can be identified when the metrology measurement does not meet the metrology rule, e.g., when the measurement falls outside the tolerance defined by the metrology rule/spec. These hotspots indicate areas of potential failure or suboptimal manufacturing performance.

In some cases, the metrology rule may also include derived metrics such as edge placement error (EPE). EPE quantifies the deviation of feature edges from their intended design positions by incorporating errors from the CD and overlay measurements. For instance, a hotspot can be identified if the EPE exceeds a predefined tolerance, reflecting a failure to meet design or process specifications. For example, a hotspot can be identified if the deviation for edge placement is larger than 5 nm.

Optionally, the identified hotspots can be used (212) to correct the design data and/or modify the manufacturing process. By way of example, in some cases, possible design corrections may include one or more of the following actions: pattern adjustments (e.g., modifying dimensions, shapes, or orientations of design features to address problematic areas), dummy fill (e.g., adding features in low-density regions to improve pattern uniformity and reduce process variability, and Optical Proximity Correction (OPC) (e.g., adjusting patterns to compensate for lithographic distortions).

In some cases, the manufacturing process can be modified by one or more of the following actions: lithography tuning (e.g., adjusting focus, exposure, or mask alignment settings), etching optimization (e.g., refining etch recipes to improve selectivity, depth control, or sidewall smoothness), deposition adjustments (e.g., modifying deposition rates, temperatures, or material compositions), and CMP adjustments (e.g., optimizing polishing parameters to enhance planarization and minimize dishing or erosion).

Referring now to FIG. 3, there is illustrated a generalized flowchart of training the ML model usable for hotspot searching in accordance with certain embodiments of the presently disclosed subject matter.

A training set can be obtained (302) (e.g., by the training module 104 when system 101 is configured as a training system). The training set comprises one or more image pairs. Each image pair includes an actual image acquired by an examination tool and a corresponding design image derived based on design data.

As used herein, the term “actual image” refers to a real image acquired by an examination tool, such as a scanning electron microscope (SEM), optical microscope, or others, from a physical training specimen/wafer. This actual image can capture the physical appearance of structures/features formed on a training specimen or wafer, serving as the ground truth for the training process.

As described above, a design image can be typically derived from electronic design data (e.g., the raw design intent, typically in the form of computer-aided design (CAD) layouts, or similar formats), which represents the intended layout of features to be fabricated on the wafer. The design image corresponds to the actual image in that the design pattern depicted in the design image corresponds with the same physical structures or features observed in the actual image.

By way of example, relevant portions of the design data, often represented in vector or polygon-based layouts, can be extracted for the specific wafer region that corresponds to the actual image. This may involve selecting the correct layer(s) or sub-region(s) of the layout, and converting those vector shapes or polygons into a rasterized format. The result is a design image that visually depicts the pattern intended to be formed on the wafer. Unlike the actual image, the design image represents the ideal layout, unaffected by process-induced variations.

In some cases, the design image and the actual image in an image pair can be aligned prior to being fed into the ML model, by undergoing an image registration process. Image registration ensures spatial correspondence between the two images, reducing misalignment and improving the training process. Depending on specific cases, the image registration can be a coarse registration (e.g., by matching the approximate field of view by comparing high-level features of the images, such as major design blocks, bounding boxes of critical structures, using simple image processing or geometric operations), or a more precise or rigid registration (e.g., fine alignment using transformations such as Affine transformation, including translations, rotations, and/or uniform scaling, to achieve pixel-level correspondence).

Proper alignment can ensure that the ML model focuses on learning finer, localized transformations, rather than compensating for large, global misalignments. This approach can accelerate the model's convergence during training, and enhances the accuracy of its simulation outputs.

Upon obtaining the training set, the ML model can be trained (304) using the training set. Specifically, for each image pair in the training set, the design image thereof can be processed (306) by the ML model to obtain a simulated image that predicts the appearance of the corresponding actual image. The ML model can be optimized (308) to reduce/minimize the difference between the simulated image and the actual image in the image pair.

The ML model referred to herein is specifically constructed for image simulation/generation based on design data. The ML model can be implemented in various network architectures. For example, the ML model can be implemented as a generative network, such as a Generative Adversarial Network (GAN), a conditional GAN, a cyclic GAN, or a similar architecture capable of taking an input image in the design domain (e.g., the design image) and producing an output image in the real/SEM-like domain. In doing so, the ML model effectively learns to mimic the appearance of semiconductor images captured by an actual imaging modality (e.g., an SEM). In some embodiments, the ML model can be implemented as a cyclic GAN, which refers to a GAN with a cyclic or cycle-consistent framework. This may include cycle GAN or any other similar models that have been developed with variations in their architectures or loss functions.

During the training process, the ML model's parameters are adjusted using backpropagation, guided by a loss function that quantifies the discrepancy between the simulated image and the actual image. By way of example, in some cases, a difference-based loss function can be employed between the simulated image and the actual image. For instance, this difference-based loss can be based on a distance metric, e.g., taking the form of an L1 or L2 loss. The L1 or L2 loss measures pixel-wise differences between the simulated and actual images, ensuring that the simulated image closely resembles the actual image on a per-pixel basis.

In some cases, the loss function may take a more sophisticated form, such as an adversarial loss in cases where the ML model is implemented in GAN-based architectures, where the generator learns to produce outputs that the discriminator cannot distinguish from real images. Other loss functions, such as, e.g., a perceptual loss for assessing similarity at a higher semantic level, improving the perceptual quality of the simulated images, can be used in addition to or in lieu of the above. The objective of the training process is to iteratively reduce the loss, driving the ML model to generate highly realistic simulated images that accurately predict the physical appearance of semiconductor patterns.

It can be recognized that the training process can enable the ML model to achieve two intertwined objectives: shape/geometry transformation, where the design data is reshaped to reflect the real-world contours and dimensions observed on the wafer, accounting for process variations; and domain translation, where the simulated image accurately replicates texture, contrast, noise, and other imaging attributes characteristic of actual wafer images (e.g., SEM modality). Although these objectives are inherently learned together within the simulation network, they collectively ensure that the simulated image not only captures the physical accuracy of the wafer patterns, but also visually mimics the appearance of actual wafer images for further analysis.

In some embodiments, one or more design images in one or more image pairs of the training set can be augmented (310) to mimic different metrology variations expected to occur in a manufacturing process of a specimen, giving rise to one or more augmented design images. Such variations reflect real-world manufacturing deviations. This augmentation process can introduce controlled variations into the design data to emulate real-world deviations that arise during fabrication. By doing so, the augmented design images can better represent the range of potential process variations, enabling the ML model to generalize more effectively.

By way of example, in some cases the augmented design images can incorporate metrology variations such as Edge Placement Error (EPE) variations, which quantify deviations between the intended and actual edge locations of design features. These variations may result from process imperfections, such as lithography misalignments, etch bias, or other manufacturing anomalies.

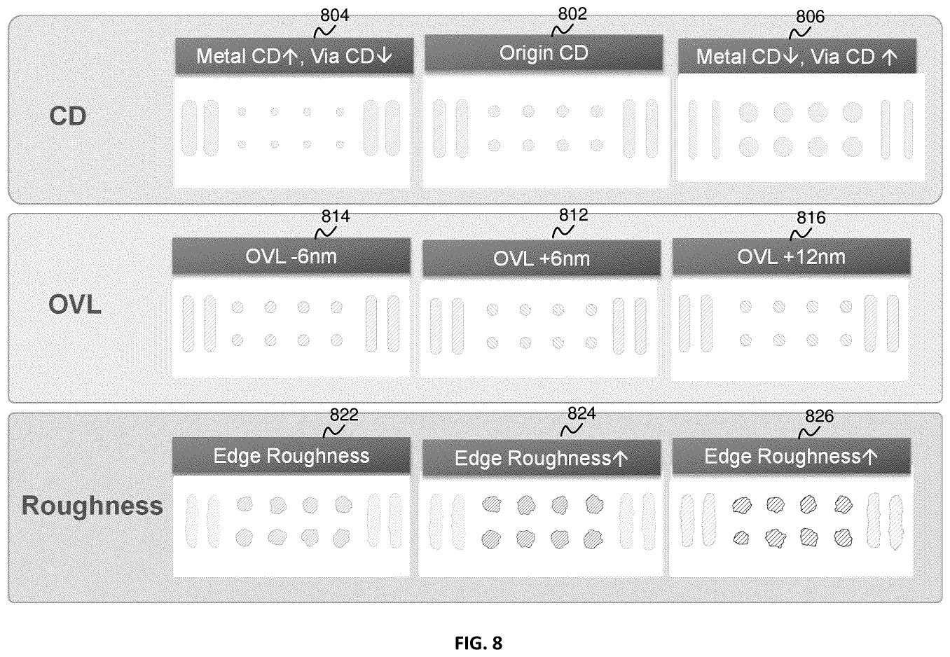

FIG. 8 illustrates examples of augmented design images for different metrology applications in accordance with certain embodiments of the presently disclosed subject matter.

For a CD application, an original design image 802 depicts a structure with an array of contacts (e.g., vias) in the center and two line structures (e.g., metal gates) on each side. These features represent two different design layers. The design image 802 can be augmented/modified to mimic potential CD-related variations expected to occur in a manufacturing process of such structure.

For instance, the line width of the metal gates can be increased while the diameters of the contacts are decreased, as exemplified in augmented design image 804. In another example, the line width of the metal gates can be decreased while the diameters of the contacts are increased, as exemplified in augmented design image 806. Additional variations, such as increasing or decreasing both line widths and diameters simultaneously, are also possible.

These augmentations represent EPE variations, as they emulate discrepancies in the placement and sizing of edges due to process variability. These variations may affect a critical measurement, such as, e.g., the spacing between the vias and the metal gates. By introducing such variations, the training process can simulate a broader range of manufacturing outcomes, even if the original training set does not include images with these specific deviations.

Similarly, for an overlay application, an original design image 812 shows the correct alignment between the two layers, where the overlay between the layers is specified as +6 nm according to the design specification. For the purpose of introducing overlay-related variations, in one example the contacts can be shifted towards the line structures on the left, resulting in an overlay value of −6 nm, as illustrated in augmented design image 814. In another example, the contacts can be shifted towards the line structures on the right, resulting in an overlay value of +12 nm, as illustrated in augmented design image 816. These shifts represent EPE variations that arise from misalignments during manufacturing. By simulating such variations, the augmented images help the ML model learn to identify and quantify overlay errors more effectively.

For an application of edge roughness, an original design image 822 depicts features with a defined level of roughness along the edges. Edge roughness refers to the variability or irregularity along the edges of a feature, often quantified as Line Edge Roughness (LER) or Line Width Roughness (LWR). These metrics assess the standard deviation of edge positions or widths along the length of a feature.

For the purpose of introducing roughness-related variations, the amount of edge roughness can be amplified to reflect moderate and severe deviations, such as illustrated in the examples of augmented design images 824 and 826.

Continuing with the description of FIG. 3, after augmentation, the one or more augmented design images can be processed (312) by the ML model, which has been partially trained using the earlier training process (block 304), to obtain one or more simulated images corresponding to the one or more augmented design images. The simulated images incorporate the augmented design variations while preserving realistic process-induced characteristics, such as texture and contrast.

The one or more augmented design images and their corresponding simulated images form one or more new image pairs (also referred to as one or more augmented image pairs). The one or more new image pairs can be added (314) to the existing training set to produce an enriched training set. The enriched training set, containing a wider variety of design and simulated image pairs, can be then used to re-train the ML model, in a similar manner as described above with reference to block 304 above. The enriched training set enables the ML model to handle a broader range of metrology variations, enhancing its robustness and generalization capabilities.

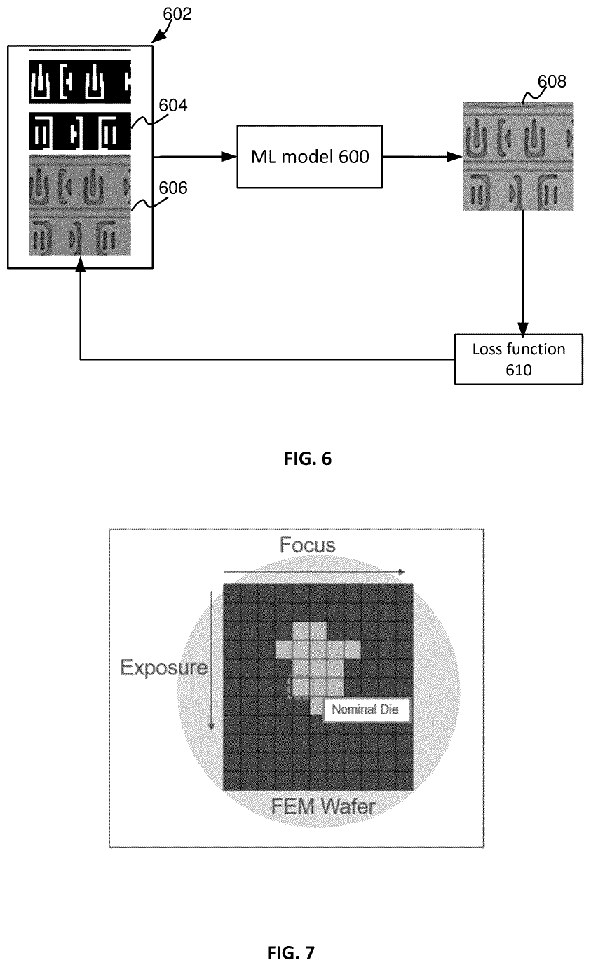

FIG. 6 shows a schematic illustration of the training process for the ML model as described above with reference to block 304 in accordance with certain embodiments of the presently disclosed subject matter.

As shown, a training image pair 602 is provided, comprising a design image 604 and an actual/real image 606. The design image 604 typically represents the idealized layout of semiconductor patterns, typically derived from design data (e.g., CAD layouts). It depicts the intended geometric shapes and dimensions of features as specified during the design phase, free from any process-induced variations. The actual image 606 captures the corresponding wafer region through a real imaging modality (e.g., an SEM). Unlike the design image, the actual image reflects process variations introduced during manufacturing, such as distortions, edge roughness, misalignments, or non-uniformities.

This training image pair 602 is input into the ML model 600. The ML model 600 is designed to perform image simulation, translating representations from the design space (e.g., design image 604) to realistic wafer images that mimic the actual image 606. Upon receiving the design image 604, the ML model 600 generates a simulated image 608 that aims to replicate the visual characteristics of the actual image 606. The simulated image captures not only the geometric transformations (e.g., reflecting deviations in feature dimensions or placement caused by process variations) but also imaging domain characteristics observed in real SEM (or other imaging modality) outputs.

To optimize the ML model, a loss function 610 measures the difference between the simulated image 608 and the actual image 606. This loss function provides feedback to the ML model, guiding it to iteratively improve its predictions and synthesize highly realistic wafer images. For instance, the loss function may take the form of a mean absolute error (L1), mean squared error (L2), perceptual loss, adversarial loss (if using a GAN setup), or any suitable measure of similarity. By minimizing this difference, the ML model learns to synthesize highly realistic wafer images from the design image.

In some embodiments, the one or more image pairs in the training set can be acquired over a Focus-Exposure Matrix (FEM) wafer. A FEM wafer is a specially fabricated test wafer designed to explore the impact of different focus and exposure settings on the printed patterns of a chip design. The FEM wafer comprises a grid or matrix of dies, each exposed under a distinct combination of focus and exposure parameters, allowing for systematic evaluation of how these variations affect the critical dimensions and structural integrity of the design. The ML model, upon being trained over the FEM wafer, is capable of simulating images acquired under different process window conditions.

FIG. 7 shows a schematic illustration of a FEM wafer in accordance with certain embodiments of the presently disclosed subject matter.

As shown, the FEM wafer is illustrated as a grid/matrix of dies organized along two primary axes: focus (represented on the x-axis) and exposure (represented on the y-axis). Each die within this matrix corresponds to a unique combination of focus and exposure settings, with incremental changes applied across the wafer to capture a range of process window conditions.

The x-axis represents variations in focus, where each position along this axis denotes a different focus setting applied during the lithography process. Moving along the x-axis, from left to right, reflects incremental adjustments to focus, capturing both under-focus and over-focus conditions relative to the center.

Similarly, the y-axis represents variations in exposure, with each position indicating a distinct exposure dose applied to that die. Moving up or down along the y-axis reflects adjustments in exposure dose, simulating conditions of under-exposure and over-exposure compared to the nominal exposure.

At the center of this matrix, a subset of dies is highlighted and labeled as nominal dies. After examination and measurement, these nominal dies are identified as having met the specification requirements, indicating that the features printed within these dies conform to the design tolerance criteria set for the process. These dies thus represent process conditions of the acceptable focus and exposure settings.

A process window qualification (PWQ) process is typically used to identify these nominal dies and determine the critical parameters of the process window defined by them. This involves characterizing the range of focus and exposure conditions that yield acceptable results, ensuring that the process remains robust within this defined window.

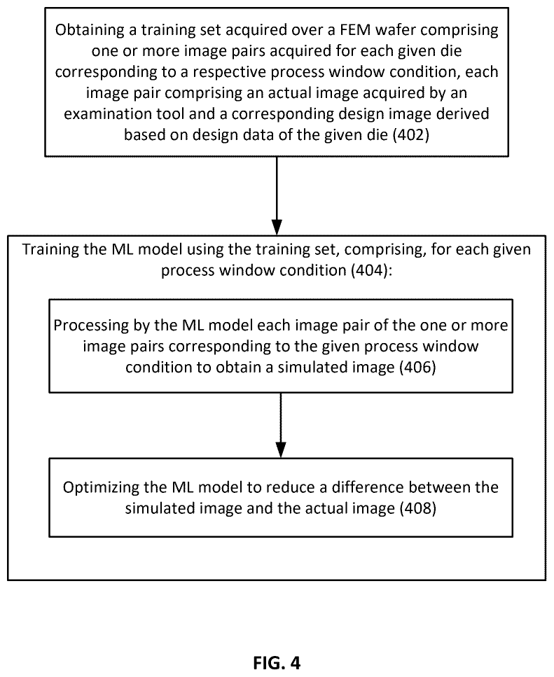

FIG. 4 illustrates a generalized flowchart of training the ML model using a FEM wafer in accordance with certain embodiments of the presently disclosed subject matter. The training process leverages the variability introduced by the FEM wafer to enhance the ML model's ability to generalize across different process window conditions.

A training set acquired over a FEM wafer can be obtained (402) (e.g., by the training module 104 when system 101 is configured as a training system). As described above, the FEM wafer comprises a plurality of dies respectively printed under a plurality of process window conditions characterized by varying combinations of focus and exposure parameters. These process variations emulate the operational range of lithographic tools and represent real-world manufacturing variability.

For each given die corresponding to a specific process window condition, the training set includes one or more image pairs. Similarly, as described above with reference to FIG. 3, each image pair comprises an actual image acquired from the given die by an examination tool and a corresponding design image derived based on design data of the given die, representing the intended layout. In some cases, the design image and the actual image in an image pair can be aligned prior to being fed into the ML model, similarly as described above.

Upon obtaining the training set, the ML model can be trained (404) using the training set acquired across the FEM wafer. Specifically, for each given process window condition of the plurality of process window conditions represented by the FEM wafer, the design image in each image pair (of the one or more image pairs corresponding to the given process window condition) can be processed (406) by the ML model to obtain a simulated image. The simulated image aims to predict the appearance of the corresponding actual image, reflecting the real-world variations introduced by the focus and exposure settings.

The ML model can be optimized (408) to reduce/minimize the difference between the simulated image and the actual image in the image pair. This optimization can be guided by loss functions, such as L1 or L2 loss, adversarial loss or perceptual loss, etc. The training procedures 406 and 408 can be performed in a manner similar to the earlier training process described above with reference to blocks 306 and 308.

By way of example, as each die in the FEM wafer corresponds to a specific process window condition (e.g., a unique combination of focus and exposure values), for a given die in the FEM wafer as exemplified in FIG. 7, one or more actual images can be acquired for the given die by an examination tool. Each actual image forms an image pair together with the design image of the given die, thereby giving rise to a training subset of one or more image pairs for the given die. These image pairs are used to train the ML model to simulate patterns under the respective process window condition.

In some embodiments, the ML model is trained separately for each die or the corresponding process window condition, using a training subset of image pairs acquired for that die. The training process can proceed sequentially, die by die, across the FEM wafer. By the end of the training process, the ML model learns to perform image simulation for all process window conditions represented on the FEM wafer. This ensures that the trained ML model can simulate images for a wide range of process window conditions, defined by various focus and exposure settings, providing robust performance across diverse manufacturing conditions.

Alternatively, rather than training a single ML model to generalize across all process window conditions, it is possible to train separate ML models for each specific condition. By way of example, for each process window condition (e.g., a unique combination of focus and exposure), a dedicated ML model is trained using the image pairs corresponding to that condition. This results in a plurality of trained ML models, each specialized for a specific process window condition.

The above different embodiments thus provide two possible solutions: a single generalized ML model capable of handling multiple process window conditions with a unified architecture, simplifying runtime application, or multiple specific ML models which may offer higher precision for individual conditions, but may require more computational resources for training and deployment.

In some cases, the hotspots identified by the ML model can be used to provide feedback for adjusting one or more manufacturing process parameters, such as focus and exposure in the lithography process. For example, hotspots indicating, e.g., overlay misalignments or critical dimension variations, can guide adjustments to focus settings, ensuring proper alignment and feature fidelity. Similarly, hotspots arising from, e.g., linewidth variations or incomplete pattern resolution, can inform on adjustments to exposure parameters, such as dose intensity or uniformity. This feedback mechanism may facilitate a closed-loop process control system, enabling continuous optimization of lithography settings and improving overall manufacturing yield.

In some further embodiments, the aforementioned image augmentation techniques can be applied on top of the training process described in FIG. 4. This integration enhances the diversity of the training set by simulating additional process-induced variations, allowing the ML model to better generalize across a wider range of manufacturing scenarios.

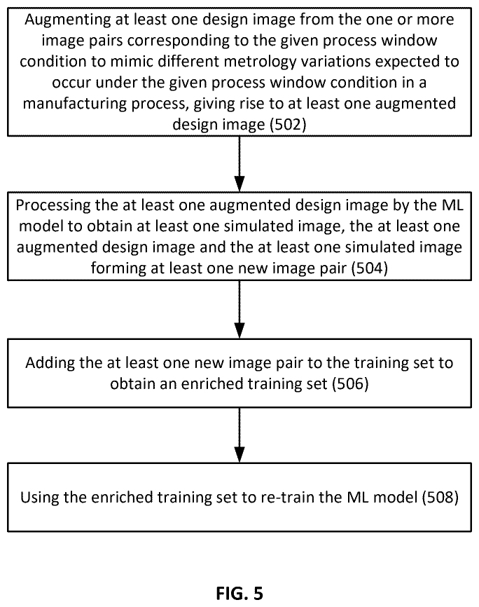

FIG. 5 illustrates a generalized flowchart of applying image augmentation to enrich the training set of a FEM wafer, and subsequently re-training of the ML model in accordance with certain embodiments of the presently disclosed subject matter. The flowchart builds upon the training process described in FIG. 4 by introducing controlled augmentations to the design images corresponding to different process window conditions, ensuring that the ML model is exposed to more diverse training data.

Following the training process of 404, at least one design image from the one or more image pairs corresponding to the given process window condition can be augmented (502) to mimic different metrology variations expected to occur under the given process window condition during the manufacturing process of a specimen. The result of this step is at least one augmented design image that emulates potential manufacturing deviations, expanding the variability represented in the training set. These variations reflect real-world deviations caused by process variability, such as lithography imperfections, etching irregularities, or deposition inconsistencies.

The at least one augmented design image can be processed (504) by the ML model to obtain at least one simulated image. The simulated image predicts the appearance of the augmented design image as it would manifest under the respective process window condition on a fabricated wafer. The at least one augmented design image and the at least one simulated image form at least one new image pair.

The at least one new image pair can be added (506) to the training set to obtain an enriched training set. This enriched training set, containing both the original image pairs and the newly augmented ones, can be then used (508) to re-train the ML model. The retraining process follows the steps outlined in FIG. 4 (404-408), where the ML model processes each design image to generate a simulated image, and minimizes the difference between simulated and actual images using a suitable loss function. By incorporating augmented data, the ML model learns to handle a broader range of variations, improving its robustness and generalization across different process conditions.

The processes of augmentation (502), generating simulated images (504), and enriching and retraining (506-508) can be performed in a similar manner to the steps described in FIG. 3 (310-314), with the added specificity of process window conditions derived from the FEM wafer.

The integration of augmentation and retraining builds upon the FEM-based training process in FIG. 4, adding another layer of diversity to the training set. By exposing the ML model to augmented design images that mimic metrology variations under specific process window conditions, this approach ensures that the training data captures a wider range of potential process-induced variations, and that the ML model learns to simulate realistic wafer images across multiple process window conditions, reflecting both natural variability and augmented scenarios.

It is to be noted that examples illustrated in the present disclosure, such as, e.g., the exemplified metrology applications, the various types of ML models, the training sets, the loss functions, and the augmentations, etc., are illustrated for exemplary purposes, and should not be regarded as limiting the present disclosure in any way. Other appropriate examples/implementations can be used in addition to, or in lieu of the above.

Overall, certain embodiments of the presently disclosed subject matter provide an ML-based solution for hotspot searching, enabling to identify potential failure points in semiconductor designs. By leveraging a machine learning (ML) model trained on image pairs comprising design and actual wafer images, the solution achieves high-fidelity simulations of final wafer appearances. The simulated images enable downstream hotspot identification by comparing metrology measurements derived from the simulated images against predefined metrology rules.

Specifically, among the advantages of certain embodiments of the presently disclosed subject matter as described herein, is the ability to achieve improved hotspot identification results. This may be primarily enabled by the simulation capability of the ML model, which accurately predicts the final wafer appearance by capturing cumulative process-induced effects across the entire manufacturing sequence. Unlike conventional lithography simulations that focus solely on optical lithographical effects, the ML model integrates the combined impacts of lithography, etching, deposition, polishing, and other possible processes in the manufacturing process of the semiconductor specimen.

By combining the advanced simulation capability with the hotspot searching workflow, which includes contour extraction, metrology measurement, and rule-based comparison, the disclosed solution provides highly accurate identification of hotspots. The integration between the simulation network and the hotspot hunting creates a unique outcome that is unmatched by traditional approaches, leading to better yield management, improved design validation, and reduced reliance on lithography simulation and costly post-fabrication inspections.

Among further advantages of certain embodiments of the presently disclosed subject matter as described herein, is the improved performance and generalization of the ML model through data augmentation and retraining. By augmenting design images with controlled variations, such as changes in critical dimension (CD), overlay offsets, and edge roughness, the proposed solution generates an enriched training set that represents a broader spectrum of real-world manufacturing deviations.

The newly created augmented design images, paired with their simulated counterparts, form additional image pairs that are incorporated into the training process. The iterative retraining allows the ML model to handle scenarios not explicitly present in the original training set, significantly enhancing its robustness and accuracy. The augmentation-based enrichment significantly enhances the ML model's ability to simulate complex patterns and deviations, resulting in better hotspot prediction performance.

Among further advantages of certain embodiments of the presently disclosed subject matter as described herein, is the ability of the ML model to generalize across different process window conditions. This is achieved through the use of Focus-Exposure Matrix (FEM) wafers, where each die is printed under a unique combination of focus and exposure values. The variability captured by FEM wafers provides a rich training set that represents a wide range of manufacturing conditions.

The ML model learns to simulate patterns under these varying conditions, ensuring that it can generate accurate wafer simulations for diverse process windows. This capability is critical for identifying hotspots in real-world scenarios where manufacturing conditions fluctuate. The proposed solution supports both single-model architectures, which generalize across all conditions, and multi-model setups, where each model is specialized for a specific condition, offering flexibility and scalability.

Among further advantages of certain embodiments of the presently disclosed subject matter as described herein, is the proactive optimization of design and manufacturing processes. By identifying hotspots early in the design stage through simulated wafer images, the proposed solution enables design corrections, such as optical proximity correction (OPC) or layout modifications, before fabrication. Similarly, process parameters, such as lithography focus or exposure settings, can be optimized based on the simulated outcomes. This proactive approach minimizes trial-and-error in the manufacturing process, reducing wafer wastage and improving overall yield.

It is to be understood that the present disclosure is not limited in its application to the details set forth in the description contained herein or illustrated in the drawings.

In the present detailed description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, as apparent from the present discussions, it is appreciated that throughout the specification discussions utilizing terms such as “simulating”, “obtaining”, “examining”, “training”, “using”, “processing”, “extracting”, “comparing”, “identifying”, “correcting”, “augmenting”, “adjusting”, “adding”, “retraining”, “aligning”, “optimizing”, or the like, refer to the action(s) and/or process(es) of a computer that manipulate and/or transform data into other data, said data represented as physical, such as electronic, quantities and/or said data representing the physical objects.

The terms “computer”, “computer-based system” or “computerized system” should be expansively construed to cover any kind of hardware-based electronic device with a data processing circuitry (e.g., digital signal processor (DSP), a graphics processing unit (GPU), a field programmable gate array (FPGA), including, by way of non-limiting example, the examination system, the hotspot searching system, and respective parts thereof disclosed in the present application. The data processing circuitry (designated also as processing circuitry) can comprise, for example, one or more processors operatively connected to computer memory, loaded with executable instructions for executing operations, as further described below. The data processing circuitry encompasses a single processor or multiple processors, which may be located in the same geographical zone, or may, at least partially, be located in different zones, and may be able to communicate together.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application-specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “specimen” used in this specification should be expansively construed to cover any kind of physical objects or substrates including wafers, masks, reticles, and other structures, combinations and/or parts thereof used for manufacturing semiconductor integrated circuits, magnetic heads, flat panel displays, and other semiconductor-fabricated articles. A specimen is also referred to herein as a semiconductor specimen, and can be produced by manufacturing equipment executing corresponding manufacturing processes.

The term “examination” used in this specification should be expansively construed to cover any kind of operations related to defect detection, defect review, and/or defect classification of various types, segmentation, and/or metrology operations during and/or after the specimen fabrication process. Examination is provided by using non-destructive examination tools during or after manufacture of the specimen to be examined. By way of non-limiting example, the examination process can include runtime scanning (in a single or in multiple scans), imaging, sampling, detecting, reviewing, measuring, classifying, and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes (SEM), atomic force microscopes (AFM), optical inspection tools, etc.

The term “metrology operation” used in this specification should be expansively construed to cover any metrology operation procedure used to extract metrology information relating to one or more structural elements on a semiconductor specimen. In some embodiments, the metrology operations can include measurement operations, such as, e.g., critical dimension (CD) measurements performed with respect to certain structural elements on the specimen, including but not limited to the following: dimensions (e.g., line widths, line spacing, contact diameters, size of the element, edge roughness, gray level statistics, etc.), shapes of elements, distances within or between elements, related angles, overlay information associated with elements corresponding to different design levels, etc. Measurement results such as measured images are analyzed, for example, by employing image-processing techniques. Note that, unless specifically stated otherwise, the term “metrology”, or derivatives thereof used in this specification, is not limited with respect to measurement technology, measurement resolution, or size of inspection area.

The term “defect” used in this specification should be expansively construed to cover any kind of abnormality or undesirable feature/functionality formed on a specimen. In some cases, a defect may be a defect of interest (DOI) which is a real defect that has certain effects on the functionality of the fabricated device, thus is in the customer's interest to be detected. For instance, any “killer” defects that may cause yield loss can be indicated as a DOI. In some other cases, a defect may be a nuisance (also referred to as “false alarm” defect) which can be disregarded because it has no effect on the functionality of the completed device and does not impact yield.

The term “defect candidate” used in this specification should be expansively construed to cover a suspected defect location on the specimen which is detected to have a relatively high probability of being a defect of interest (DOI). Therefore, a DOI candidate, upon being reviewed/tested, may actually be a DOI, or, in some other cases, it may be nuisances, or random noise that can be caused by different variations (e.g., process variation, color variation, mechanical and electrical variations, etc.) during inspection.

The term “design data” used in the specification should be expansively construed to cover any data indicative of hierarchical physical design (layout) of a specimen. Design data can be provided by a respective designer and/or can be derived from the physical design (e.g., through complex simulation, simple geometric and Boolean operations, etc.). Design data can be provided in different formats as, by way of non-limiting examples, GDSII format, OASIS format, etc. Design data can be presented in vector format, grayscale intensity image format, or otherwise.

The term “image(s)” or “image data” used in the specification should be expansively construed to cover any original images/frames of the specimen captured by an examination tool during the fabrication process, derivatives of the captured images/frames obtained by various pre-processing stages, and/or computer-generated synthetic images (in some cases based on design data). Depending on the specific way of scanning (e.g., one-dimensional scan such as line scanning, two-dimensional scan in both x and y directions, or dot scanning at specific spots, etc.), image data can be represented in different formats, such as, e.g., as a gray level profile, a two-dimensional image, or discrete pixels, etc. It is to be noted that in some cases the image data referred to herein can include, in addition to images (e.g., captured images, processed images, etc.), numeric data associated with the images (e.g., metadata, hand-crafted attributes, etc.). It is further noted that images or image data can include data related to a processing step/layer of interest, or a plurality of processing steps/layers of a specimen.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the present detailed description, numerous specific details are set forth in order to provide a thorough understanding of the methods and apparatus.

It will also be understood that the system according to the present disclosure may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

1. A computerized system for hotspot searching, the system comprising a processing circuitry configured to:
obtain design data usable for manufacturing a semiconductor specimen;
process the design data using a machine learning (ML) model, to obtain a simulated image predicting appearance of an actual image of the semiconductor specimen, the ML model being previously trained for design-based image simulation to simulate one or more physical effects resulting from a manufacturing process of the specimen;
extract one or more contours from the simulated image;
obtain a metrology measurement pertaining to a metrology application based on the extracted contours; and
compare the metrology measurement with respect to a metrology rule related to the metrology application to identify one or more hotspots on the design data.

2. The computerized system according to claim 1, wherein the metrology application is one of: critical dimension (CD), overlay, and roughness.

3. The computerized system according to claim 1, wherein the one or more physical effects represent a cumulative process-induced effect from a plurality of manufacturing steps including lithography, etching, deposition, polishing, and resist.

4. The computerized system according to claim 1, wherein the one or more hotspots are identified where the metrology measurement does not meet the metrology rule.

5. The computerized system according to claim 1, wherein the identified hotspots are usable for correcting the design data and/or modifying the manufacturing process.

6. The computerized system according to claim 1, wherein the ML model has been previously trained using a training set comprising one or more image pairs, each image pair comprising an actual image acquired by an examination tool and a corresponding design image derived based on design data.

7. The computerized system according to claim 6, wherein the training set further comprises one or more augmented image pairs, each augmented image pair comprising an augmented design image generated by augmenting a design image with one or more metrology variations, and a simulated image generated by the ML model from the augmented design image.

8. The computerized system according to claim 1, wherein the ML model has been previously trained using a training set acquired over a Focus-Exposure Matrix (FEM) wafer.

9. The computerized system according to claim 8, wherein the identified hotspots are usable to provide feedback for adjusting one or more manufacturing process parameters including focus and exposure.

10. A computerized method of training a machine learning (ML) model, the method comprising:
obtaining a training set comprising one or more image pairs, each image pair comprising an actual image acquired by an examination tool and a corresponding design image derived based on design data;
training the ML model using the training set, comprising, for each image pair, processing by the ML model the design image in the image pair to obtain a simulated image, and optimizing the ML model to reduce a difference between the simulated image and the actual image in the image pair;
augmenting one or more design images in one or more image pairs of the training set to mimic different metrology variations expected to occur in a manufacturing process of a specimen, giving rise to one or more augmented design images;
processing the one or more augmented design images by the ML model to obtain one or more simulated images, the one or more augmented design images and the one or more simulated images forming one or more new image pairs;
adding the new image pairs to the training set to obtain an enriched training set; and
using the enriched training set to re-train the ML model.

11. The computerized method according to claim 10, wherein the metrology variations are edge placement error (EPE) variations with respect to one or more design features in the one or more design images.

12. The computerized method according to claim 11, wherein the EPE variations are related to a metrology application selected from CD, overlay, and roughness.

13. The computerized method according to claim 10, wherein the training set is acquired over a Focus-Exposure Matrix (FEM) wafer comprising a plurality of dies respectively printed under a plurality of process window conditions characterized by varying combinations of focus and exposure parameters, such that the ML model, upon being trained, is capable of simulating images acquired under different process window conditions.

14. The computerized method according to claim 10, further comprising aligning the design image and the actual image in each image pair prior to processing by the ML model.

15. The computerized method according to claim 10, wherein the ML model is a cyclic generative adversarial network (GAN).

16. A computerized method of training a machine learning (ML) model, the method comprising:
obtaining a training set acquired over a Focus-Exposure Matrix (FEM) wafer, the FEM wafer comprising a plurality of dies respectively printed under a plurality of process window conditions characterized by varying combinations of focus and exposure parameters, the training set comprising one or more image pairs acquired for each given die corresponding to a respective process window condition, each image pair comprising an actual image acquired from the given die by an examination tool and a corresponding design image derived based on design data of the given die;
training the ML model using the training set, comprising, for each given process window condition:
processing the design image in each image pair of the one or more image pairs corresponding to the given process window condition by the ML model to obtain a simulated image; and
optimizing the ML model to reduce a difference between the simulated image and the actual image;
wherein the ML model, upon being trained, is capable of simulating images acquired under different process window conditions.

17. The computerized method according to claim 16, wherein the training of the ML model for each given process window condition further comprises:
augmenting at least one design image from the one or more image pairs corresponding to the given process window condition to mimic different metrology variations expected to occur under the given process window condition in a manufacturing process of a specimen, giving rise to at least one augmented design image;
processing the at least one augmented design image by the ML model to obtain at least one simulated image, the at least one augmented design image and the at least one simulated image forming at least one new image pair;
adding the at least one new image pair to the training set to obtain an enriched training set; and
using the enriched training set to re-train the ML model.

18. The computerized method according to claim 17, wherein the metrology variations are edge placement error (EPE) variations with respect to one or more design features in the one or more design images.

19. The computerized method according to claim 18, wherein the EPE variations are related to a metrology application which is one of CD, overlay, and roughness.

20. A non-transitory computer readable storage medium tangibly embodying a program of instructions that, when executed by a computer, cause the computer to perform a method of hotspot searching, the method comprising:
obtaining design data usable for manufacturing a semiconductor specimen;
processing the design data using a machine learning (ML) model, to obtain a simulated image predicting appearance of an actual image of the semiconductor specimen, the ML model being previously trained for design-based image simulation to simulate one or more physical effects resulting from a manufacturing process of the specimen;
extracting one or more contours from the simulated image;
obtaining a metrology measurement pertaining to a metrology application based on the extracted contours; and
comparing the metrology measurement with respect to a metrology rule related to the metrology application to identify one or more hotspots on the design data.
